(19) United States
(12) Patent Application Publication
(10) Pub. No.: US 2020/0150711 A1
(43) Pub. Date: May 14, 2020

(54) METHOD OF GENERATING CLOCK OUTPUT TO SEMICONDUCTOR DEVICE FOR TESTING SEMICONDUCTOR DEVICE, AND CLOCK CONVERTER AND TEST SYSTEM PERFORMING THE METHOD

(71) Applicant: SAMSUNG ELECTRONICS CO., LTD., Suwon-si (KR)

(72) Inventors: Yong-jeong KIM, Cheonan-si (KR); Seong-gwon JANG, Asan-si (KR)

(21) Appl. No.: 16/678,662

(22) Filed: Nov. 8, 2019

(30) Foreign Application Priority Data
Nov. 9, 2018 (KR) 10-2018-0137602

(51) Int. Cl. G06F 1/08; H03L 7/097; H03C 3/09

(52) U.S. Cl. CPC G06F 1/08; H03C 3/0966; H03L 7/097

(57) ABSTRACT

A clock converter to output a clock signal for testing a semiconductor device includes: a clock input terminal to receive an input clock having an input frequency; a first frequency conversion circuit to receive the input clock and output a first conversion clock having a first frequency by increasing the input frequency using a fixed multiplier; a second frequency conversion circuit to receive the input clock and output a second conversion clock having a second frequency, greater than the first frequency, by increasing the input frequency using a variable multiplier; and a selection circuit to output the first conversion clock or the second conversion clock according to a mode selection signal.

### CROSS-REFERENCE TO RELATED APPLICATION

Korean Patent Application No. 10-2018-0137602, filed on Nov. 9, 2018, in the Korean Intellectual Property Office, and entitled: “Method of Generating Clock Output to Semiconductor Device for Testing Semiconductor Device, and Clock Converter and Test System Including the Method,” is incorporated by reference herein in its entirety.

### BACKGROUND

### 1. Field

Embodiments relate to a method of generating a clock output to a semiconductor device for testing the semiconductor device, and a clock converter and a test system performing the method.

### 2. Description of the Related Art

Electronic devices have become more compact, of high-performance, and of large-capacity according to rapid development of the electronic industry and demands of users. Accordingly, test processes of semiconductor devices included in electronic devices have also become complicated. As an example, a high performance memory semiconductor device performs various functions, e.g., a read operation and a write operation with high bandwidth. When such a high performance memory semiconductor device is under test (DUT), a test device needs to be designed to test with the high bandwidth.

### SUMMARY

According to an embodiment, there is provided a clock converter to output a clock signal for testing a semiconductor device, the clock converter including: a clock input terminal to receive an input clock having an input frequency; a first frequency conversion circuit to receive the input clock and output a first conversion clock having a first frequency by increasing the input frequency using a fixed multiplier; a second frequency conversion circuit to receive the input clock and output a second conversion clock having a second frequency, greater than the first frequency, by increasing the input frequency using a variable multiplier; and a selection circuit to output the first conversion clock or the second conversion clock according to a mode selection signal.

According to an embodiment, there is provided a semiconductor test system configured to test a semiconductor device, the semiconductor test system including: automatic test equipment (ATE) including a test logic to transmit and receive data for testing the semiconductor device, output an input clock having an input frequency, and output a mode selection signal having different values according to a frequency band of an output clock for testing the semiconductor device; and a socket board electrically connected to the ATE including a clock converter. The clock converter includes: a clock input terminal to receive the input clock; a first frequency conversion circuit to receive the input clock and output a first conversion clock having a first frequency greater than the input frequency; a second frequency conversion circuit to receive the input clock and output a second conversion clock having a second frequency greater than the first frequency; and a selection circuit to output the output clock based on the first conversion clock or the second conversion clock according to the mode selection signal to the semiconductor device.

According to an embodiment, there is provided a method of converting a clock signal for testing a semiconductor device, the method including: receiving an input clock having an input frequency; generating a first conversion clock having a first frequency greater than the input frequency by multiplying the input frequency by a fixed multiplier; generating a second conversion clock having a second frequency greater than the first frequency by multiplying the input frequency by the variable multiplier; and outputting the first conversion clock or the second conversion clock according a mode selection signal.

### BRIEF DESCRIPTION OF THE DRAWINGS

Features will become apparent to those of skill in the art by describing in detail exemplary embodiments with reference to the attached drawings in which:

FIG. 1 illustrates a test system according to an embodiment;

FIG. 2 illustrates a socket board according to an embodiment;

FIG. 3 illustrates a diagram for explaining a clock converter according to an embodiment;

FIG. 4 illustrates a diagram for explaining an XOR gate according to an embodiment;

FIG. 5 illustrates a diagram for explaining a second frequency conversion circuit according to an embodiment;

FIG. 6 illustrates a diagram for explaining in detail a second frequency conversion circuit according to an embodiment;

FIG. 7 illustrates a diagram for explaining a second frequency conversion circuit according to an embodiment;

FIGS. 8A and 8B illustrate an input clock, an output clock, and data in a first frequency conversion circuit according to embodiments;

FIG. 9 illustrates an input clock, an output clock, and data in a first frequency conversion circuit, according to an embodiment;

FIG. 10 illustrates a flowchart of a method of generating an output clock for testing a semiconductor device, according to an embodiment;

FIG. 11 illustrates a detailed flowchart of a method of generating an output clock for testing a semiconductor device, according to an embodiment; and

FIG. 12 illustrates a diagram for explaining a test system according to an embodiment.

### DETAILED DESCRIPTION

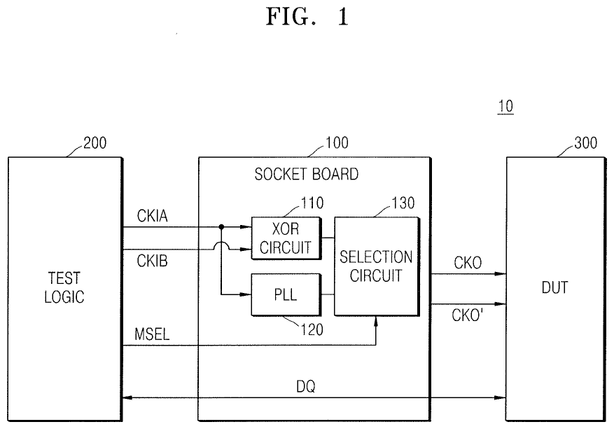

FIG. 1 illustrates a test system 10 according to an embodiment. Referring to FIG. 1, the test system 10 for testing a semiconductor device may include one or more device under tests (DUT) 300 to be tested, as well as a socket board 100 and a test logic 200. The socket board 100 may include a first frequency conversion circuit 110, a second frequency conversion circuit 120, and a selection circuit 130.

The first frequency conversion circuit 110 may increase an input frequency of a first input clock CKIA and second input clock CKIB by a fixed multiplier to output a clock having a first frequency greater than the input frequency. The second frequency conversion circuit 120 may increase the input frequency by a variable multiplier, greater than the fixed multiplier, to output a clock having a second frequency greater that the first frequency. Hereinafter, a multiplier may denote an integer multiplied with the input frequency of an input signal.

For example, the first frequency conversion circuit 110 may multiply the input frequency of the first and second input clocks CKIA and CKIB by two, and the second frequency conversion circuit 120 may multiply the input frequency of the first input clock CKIA by a variable multiplier, e.g., four, eight, or any other number greater than the fixed multiplier.

The first frequency conversion circuit 110 may be implemented by an exclusive OR (XOR) circuit including an XOR gate. The second frequency conversion circuit 120 may be implemented by a phase locked loop (PLL) circuit including a PLL.

The socket board 100 may be implemented in various forms and at various locations to process the first and second input clocks CKIA and CKIB output by the test logic 200 and output the processed first and second input clocks CKIA and CKIB as an output clock CK0 to the DUT 300. In this case, the test logic 200 may be included in automated test equipment (ATE), and the socket board 100 may be on one side of the ATE.

The test logic 200 may output the first and second input clocks CKIA and CKIB and data DQ to test the DUT 300. For example, the test logic 200 may test the DUT 300 based on whether the data DQ suitable for the first and second input clocks CKIA and CKIB output by the test logic 200 has been received. The DUT 300 may receive the output clock CKO and the data DQ based on the first and second input clocks CKIA and CKIB. The data DQ may be transmitted/received between the test logic 200 and the DUT 300 via the socket board 100.

Referring to FIG. 1, the DUT 300 is illustrated as one semiconductor device for convenience of explanation. In an implementation, the DUT 300 may include a plurality of semiconductor devices. As an example, a semiconductor device may include a memory device including a memory cell array. For example, the memory device may include dynamic random access memory (RAM) (DRAM), e.g., double data rate (DDR) synchronous DRAM (SDRAM), low power DDR (LPDDR), graphics DDR (GDDR) SDRAM, Rambus DRAM (RDRAM), and the like. Alternatively, the memory device may include a nonvolatile memory, e.g., a flash memory, magnetic RAM (MRAM), ferroelectric RAM (FeRAM), phase change RAM (PRAM), resistive RAM (ReRAM), and the like.

According to an embodiment, the socket board 100 may process the first and second input clocks CKIA and CKIB received from the test logic 200 to be compatible with the DUT 300 and output the output clock CKO. For example, when bandwidths of the first and second input clocks CKIA and CKIB that the test logic 200 outputs is limited to x Gbps (where, x is an integer), the socket board 100 may multiply the base frequency of the first and second input clocks CKIA and CKIB to output the output clock CKO having a bandwidth higher than the bandwidths of the first and second input clocks CKIA and CKIB, e.g., 2x Gbps and 4x Gbps. The socket board 100 may output an inverted output clock CKO′ together with the output clock CKO. In this case, the socket board 100 may have the same number of channels through which the first and second input clocks CKIA and CKIB is received as the number of channels through which the output clock CKO is output, i.e., a ratio of input channels to output channels may be 1:1. Thus, channel resources may be reduced.

According to an embodiment, the socket board 100 may receive a mode selection signal MSEL from the test logic 200, select a signal output by one of the first frequency conversion circuit 110 and the second frequency conversion circuit 120, and transmit the output clock CKO to the DUT 300. When the selection circuit 130 receives the mode selection signal MSEL having a first value, the selection circuit 130 may amplify the signal received from the first frequency conversion circuit 110 and provide the amplified signal as the output clock CKO. When the selection circuit 130 receives the mode selection signal MSEL having a second value, the selection circuit 130 may amplify the signal received from the second frequency conversion circuit 120 and provide the amplified signal as the output clock CKO.

The first frequency conversion circuit 110 may receive a first input clock CKIA and a second input clock CKIB having the same input frequency. For example, the test logic 200 may output the second input clock CKIB having a phase shifted by about 90 degrees from the phase of the first input clock CKIA.

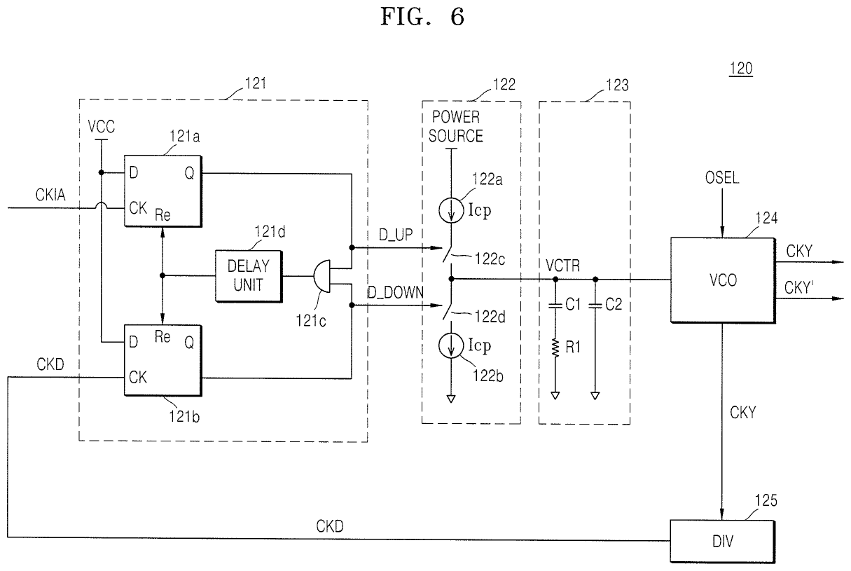

The first frequency conversion circuit 110 may perform an XOR operation on the first input clock CKIA and the second input clock CKIB, and output a frequency signal obtained by multiplying the input frequency of the first input clock CKIA by two to the selection circuit 130. The second frequency conversion circuit 120 may perform a phase locking operation with the first input clock CKIA as an input frequency signal. In this case, the second frequency conversion circuit 120 may output a signal of a frequency band allocated to each of a plurality of voltage-controlled oscillators included therein to the selection circuit 130, as described below with reference to FIG. 6.

According to an embodiment, since the first frequency conversion circuit 110 performs the XOR operation on the first input clock CKIA and the second input clock CKIB in real time, little delay time may occur and a wide frequency band may be covered. Since the first frequency conversion circuit 110 including the XOR gate generates the output clock CKO having a first frequency without a delay even when input frequencies of the first and second input clocks CKIA and CKIB changes in real time, the first frequency conversion circuit 110 may test the DUT 300 which requires the output clock CKO to have variable frequencies.

The second frequency conversion circuit 120 may reduce noise of the output clock CKO by comparing phases of the first input clock CKIA to a fed back signal output from the second frequency conversion circuit 120. In addition, the second frequency conversion circuit 120 may perform frequency multiplication by various multiples. As the frequency conversion circuit 120 only uses the first input clock CKIA to generate a clock having the second frequency, the number of input channels of the second frequency conversion circuit 120 may be less than the number of input channels of the first frequency conversion circuit 110, i.e., a ratio of input channels to output channels may be 1:2. Thus, channel resources may be further reduced.

Since the frequency multiplication of the second frequency conversion circuit 120 is flexible, the second frequency conversion circuit 120 may generate the output clock CKO of a high frequency even if the input frequency of the input signal is low. In addition, by detecting a phase difference, the second frequency conversion circuit 120 may generate the output clock CKO having reduced noise as compared with the input signal.

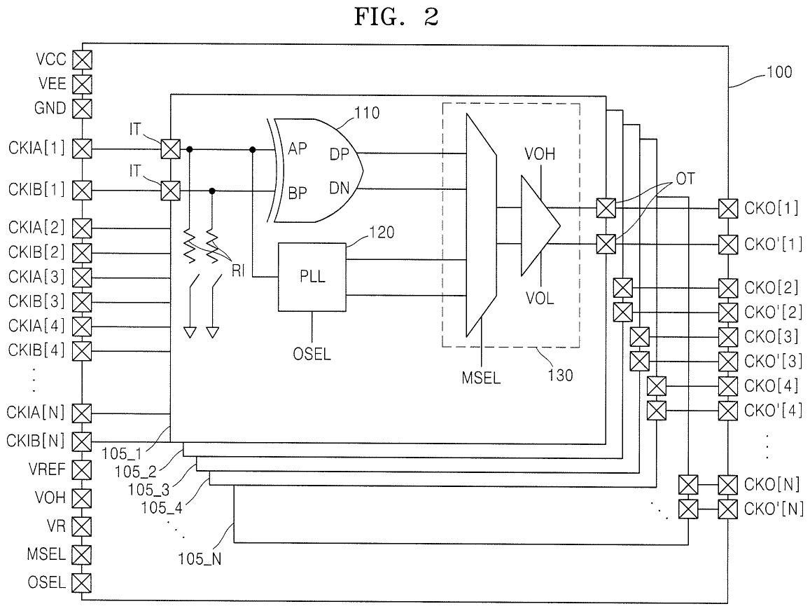

FIG. 2 illustrates the socket board 100 according to an embodiment. Referring to FIG. 2, the socket board 100 may include first through N^{th} (N is an integer greater than one) socket chips 105_1 through 105_N, each of the first through N^{th} socket chips 105_1 through 105_N may include the first frequency conversion circuit 110, the second frequency conversion circuit 120, and the selection circuit 130, and may further include an input termination RI, a clock input terminal IT, and a clock output terminal OT.

As an example, the first through N^{th} socket chips 105_1 through 105_N may be stacked on each other and packaged together into one package. As another example, the first through N^{th} socket chips 105_1 through 105_N may be apart from each other two-dimensionally on the socket board 100. In other words, the first through N^{th} socket chips 105_1 through 105_N may be included on the socket board 100 in various configurations in which the first through N^{th} socket chips 105_1 through 105_N output first through N^{th} output clocks CKO[1] through CKO[N] and/or inverted first through N^{th} output clocks CKO′[1] through CKO′[N] to the DUT 300, respectively.

For example, when a plurality of DUTs 300 are to be tested, the test logic 200 may output a first input clock CKIA[1] and a second input clock CKIB[1] for testing the first DUT, a first input clock CKIA[ ] and a second input clock CKIB[ ] for testing the second DUT, and so forth. Then the socket board 100 outputs the first output clock CKO[1] and the first inverted first output clock CKO′[1] may be output to a first DUT, the second test clock CKO[2] and the inverted second output clock CKO′[2] may be output to a second DUT, and so forth in response to the input clocks.

The socket board 100 may include a plurality of terminals for inputting various signals and voltages. The socket board 100 may include a power supply voltage (VCC) terminal, a ground voltage (VEE) terminal, and a ground (GND) terminal for powering the socket board 100 and/or the DUT 300.

The socket board 100 may include a plurality of input clock (CKI) terminals. For example, the socket board 100 may include terminals to output the first input clock CKIA[1] and the second input clock CKIB[1] to be input to the first socket chip 105_1. The socket board 100 may include a plurality of terminals to output the first input clocks (CKIA[1] through CKIA[N]) and the second input clocks (CKIB[1] through CKIB[N]) to be input from the test logic 200 via the clock input terminals IT of the first through N^{th} socket chips 105_1 through 105_N, respectively. The socket board 100 may include a reference voltage (VREF) terminal for logically determining (for example, determining as a logic high or a logic low) the first and second input clocks CKIA and CKIB, an alternating current (AC) signal, and other AC signals input or output to and/or from each configuration included in the first through N^{th} socket chips 105_1 through 105_N. The socket board 100 may include a terminal for determining a maximum drive voltage VOH and a drive voltage swing level VR supplied to various configurations included in the socket chip 105 that includes the selection circuit 130. The socket board 100 may include a terminal for receiving the mode selection signal MSEL applied to the selection circuit 130 and an oscillator selection signal OSEL applied to the second frequency conversion circuit 120.

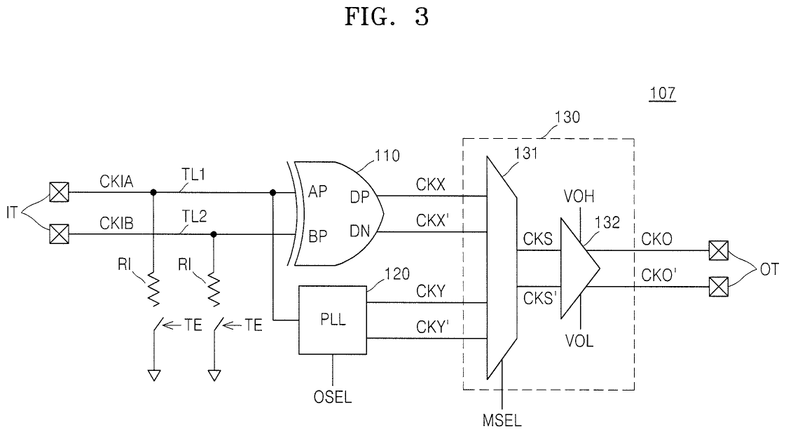

The socket board 100 may include a plurality of terminals for outputting various signals and voltages. The socket board 100 may include terminals for transmitting to the DUT 300 the first through N^{th} output clocks CKO[1] through CKO[N] and the inverted first through N^{th} output clocks CKO′[1] through CKO′[N] output from the first through N^{th} socket chips 105_1 through 105_N, respectively. A configuration and function of each of the first through N^{th} socket chips 105_1 through 105_N is described below with reference to FIG. 3.

FIG. 3 is a diagram for explaining a clock converter 107 according to an embodiment. Referring to FIG. 3, each of the first through N^{th} socket chips 105_1 through 105_N may include the clock converter 107, and the clock converter 107 may include the first frequency conversion circuit 110, the second frequency conversion circuit 120, the selection circuit 130, the clock input terminal IT, and the clock output terminal OT. In addition, the clock converter 107 may further include the input termination RI for matching an input impedance observed from the clock input terminal IT.

According to an embodiment, the first frequency conversion circuit 110 may receive the first input clock CKIA and the second input clock CKIB and output a first conversion clock CKX and/or an inverted first conversion clock CKX′. For example, a frequency of the first conversion clock CKX may be twice as high as a frequency of the first input clock CKIA. To this end, the first frequency conversion circuit 110 may be implemented as an integrated circuit (IC) including an XOR gate. For example, the first frequency conversion circuit 110 may include the XOR gate that generates the first conversion clock CKX by performing the XOR operation on the first input clock CKIA and the second input clock CKIB, and an inverter that generates the inverted first conversion clock CKX′ that is an inverted signal of the first conversion clock CKX.

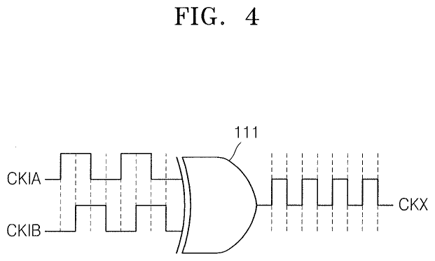

FIG. 4 is a diagram for explaining an XOR gate 111 according to an embodiment. Referring to FIGS. 3 and 4, the first frequency conversion circuit 110 may include the XOR gate 111 that may be implemented in various forms, e.g., hardware and/or software. According to a known truth table, the XOR gate 111 may output 0 when the first input and the second input are the same, i.e., 0 and 0 or 1 and 1, respectively, and may output 1 when the first input and the second input are different, i.e., 0 and 1 or 1 and 0, respectively. The first input clock CKIA and the second input clock CKIB input to the XOR gate 111 may have phases shifted by about a ¼ period or about 90 degrees. As the first input clock CKIA and the second input clock CKIB having the phases shifted by about 90 degrees are input, the XOR gate 111 may output the first conversion clock CKX having a first frequency that is twice the input frequency of the first and second input clocks CKIA and CKIB.

According to the first frequency conversion circuit 110 and the XOR gate 111 according to an embodiment, a delay may be reduced by receiving the first and second input clocks CKIA and CKIB shifted by about 90 degrees and generating the first conversion clock CKX in real time. Since there is no limit on the input frequencies of the first and second input clocks CKIA and CKIB, a wide frequency band may be covered. However, the first frequency conversion circuit 110 may be limited to multiplying an input frequency by a fixed amount, e.g., two.

Referring again to FIG. 3, the second frequency conversion circuit 120 may receive the first input clock CKIA and output a second conversion clock CKY and/or an inverted second conversion clock CKY′. For example, a frequency of the second conversion clock CKY may be k times higher than the input frequency of the first input clock CKIA.

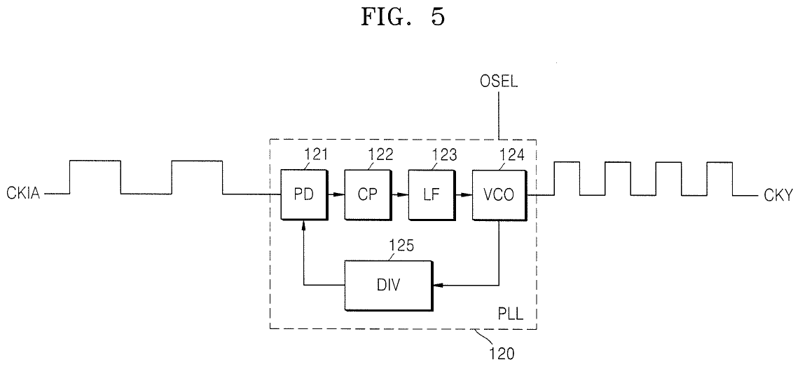

To this end, the second frequency conversion circuit 120 may be implemented as the phase locked loop PLL. For example, the second frequency conversion circuit 120 may compare the phases of the first input clock CKIA with the fed back second conversion clock CKY, generate a signal corresponding to a phase difference, convert the generated signal to a voltage, and output an oscillation signal according to the voltage. The second frequency conversion circuit 120 may include at least one voltage-controlled oscillator and may select an oscillator outputting a required frequency band among a plurality of voltage-controlled oscillators according to the oscillator selection signal OSEL. This is described in detail later with reference to FIGS. 5 and 6.

According to an embodiment, a maximum value of the second frequency of the second conversion clock CKY may be higher than the maximum value of the first frequency of the first conversion clock CKX. For example, the first frequency conversion circuit 110 may be twice the input frequency, and the second frequency conversion circuit 120 may, by variably controlling a frequency division ratio of a frequency divider 125, output the second conversion clock CKY that has been multiplied by a variable number (e.g. four, or any integer greater than two).

When the second frequency conversion circuit 120 is used to generate the output clock CKO of a high frequency, the input frequencies of the first and second input clocks CKIA and CKIB may be low. For example, when an output clock CKO of about 20 Gbps is to be generated, the first frequency conversion circuit 110 needs the first and second input clocks CKIA and CKIB to have an input frequency of about 10 Gbps. In contrast, when the second frequency conversion circuit 120 can multiply the input frequency four, the first input clock CKIA may have an input frequency of only about 5 Gbps to generate an output clock CKO of about 20 Gbps. Accordingly, cost and time for the test logic 200 to output the high first and second input clocks CKIA and CKIB may be reduced.

The clock converter 107 according to an embodiment may be provided with a transmission line to input the first input clock CKIA and/or the second input clock CKIB to the first frequency conversion circuit 110 and the second frequency conversion circuit 120. A first transmission line TL1 is connected to the clock input terminal IT, to which the first input clock CKIA is input, and to the first frequency conversion circuit 110. The first transmission line may be branched and connected to the second frequency conversion circuit 120. A second transmission line TL2 is connected to the clock input terminal IT, to which the second input clock CKIB is input, and to the first frequency conversion circuit 110. In addition, the input terminations RI may be provided along the transmission lines branched from the first transmission line T11 and the second transmission line TL2, respectively, and a switch may be connected in series to each of the input terminations RI.

The input terminations RI according to an embodiment may be connected in parallel to the clock input terminals IT and the first frequency conversion circuit 110. The impedance values of the input terminations RI may have an impedance in a direction of the first frequency conversion circuit 110 and the second frequency conversion circuit 120 matches an impedance observed in an opposite direction thereof, e.g., an input impedance.

The input terminations RI may be activated according to a termination enable signal TE. For example, the input terminations RI may each connected in series to the switch, and the termination enable signal TE may control the switch to be turned on or off. The termination enable signal TE may be input from the test logic 200 to the clock converter 107 via the socket board 100.

The selection circuit 130 according to an embodiment may receive the first conversion clock CKX, the inverted first conversion clock CKX′, the second conversion clock CKY, and the inverted second conversion clock CKY′, and output the output clock CKO and the inverted output clock CKO′ that are generated by amplifying at least one of the received conversion clocks (CKX and CKY) and the received inverted conversion clocks (CKX′ and CKY′), respectively.

The selection circuit 130 may include a multiplexer 131 and an operational amplifier circuit 132. The multiplexer 131 may select a signal output from one of the first frequency conversion circuit 110 and the second frequency conversion circuit 120 according to the mode selection signal MSEL and output the selected signal as a selection clock CKS. For example, when the multiplexer 131 receives the mode selection signal MSEL having a first value, the multiplexer 131 may output the first converted clock CKX input from the first frequency conversion circuit 110 as the selection clock CKS and may output the inverted first conversion clock CKX′ as an inverted selection clock CKS′. When the multiplexer 131 receives the mode selection signal MSEL having a second value, the multiplexer 131 may output the second converted clock CKY input from the second frequency conversion circuit 120 as the selection clock CKS and may output the inverted second conversion clock CKY′ as an inverted selection clock CKS′.

The operational amplifier circuit 132 may output the output clock CKO and the inverted output clock CKO′ that are obtained by amplifying the received selection clock CKS and the inverted selection clock CKS′, respectively. According to an embodiment, the operational amplifier circuit 132 may amplify the selection clock CKS and the inverted selection clock CKS' based on the maximum drive voltage level VOH and a minimum drive voltage level VOL. The minimum driving voltage level VOL may be a value obtained by subtracting the driving voltage swing level VR from the maximum driving voltage level VOH received from the outside of the socket board 100 of FIG. 2 described above. For example, the operational amplifier circuit 132 may generate the output clock CKO obtained by amplifying the selection clock CKS equal to or less than the maximum driving voltage level VOH and equal to or greater than the minimum driving voltage level VOL.

FIG. 5 is a diagram for explaining the second frequency conversion circuit 120 according to an embodiment. Referring to FIG. 5, the second frequency conversion circuit 120 may include a phase detector (PD) 121, a charge pump unit (CP) 122, a loop filter unit (LF) 123, a voltage controlled oscillating unit (VCO) 124, and a frequency divider (DIV) 125. The PD 121 may compare phases of the first input clock CKIA with a clock fed back from the DIV 125. The CP 122 may generate a signal corresponding to a phase difference. The LF 123 may convert the generated signal to a voltage. The VCO 124 may output an oscillation signal according to the voltage. The DIV 125 may divide a frequency of the oscillation signal and provide the divided frequency to the PD 121. In other words, the second frequency conversion circuit 120 may be implemented as the PLL.

The second frequency conversion circuit 120 may receive the oscillator selection signal OSEL, select one of a plurality of voltage controlled oscillators included in the VCO 124, and output the second conversion clock CKY based on an output of the selected voltage controlled oscillator. This is described below with reference to FIG. 6.

FIG. 6 is a diagram for explaining in detail the second frequency conversion circuit 120 according to an embodiment. The PD 121 according to an example embodiment may compare the phase difference between a divided clock CKD output from the DIV 125 and the first input clock CKIA and generate a phase difference signal. The phase difference signal may include an up detection signal D_UP and a down detection signal D_DOWN.

Referring to FIG. 6, the PD 121 may include a first flip-flop 121a, a second flip-flop 121b, an AND gate 121c, and a delay unit 121d. The first input clock CKIA may be input to a clock input terminal CK of the first flip-flop 121a, and the divided clock CKD output from the DIV 125 may be input to the clock input terminal CK of the second flip-flop 121b. Data input terminals D of the first and second flip-flops 121a and 121b may be connected to the power supply voltage VCC. The up detection signal D_UP may be output from a data output terminal Q of the first flip-flop 121a, and the down detection signal D_DOWN may be output from the data output terminal Q of the second flip-flop 121b. For example, the up detection signal D_UP indicates that the first input clock CKIA has phase earlier than the frequency of the divided clock CKD, and the down detection signal D_DOWN indicates the opposite. The AND gate 121c receives the up detection signal D_UP and the down detection signal D_DOWN, and may perform an AND operation thereon. The delay unit 121d may delay an output of the AND gate 121c by a certain time and provide a reset signal to reset terminals Re of the first and second flip-flops 121a and 121b. Since a certain time is required while a first charge pump current source 122a and a second charge pump current source 122b included in the CP 122 perform a turn-on or turn-off operation, the delay unit 121d may delay the output therefrom by a certain time.

When the phase of the first input clock CKIA is earlier than the phase of the divided clock CKD, the PD 121 may transmit the up detection signal D_UP to the CP 122. When the phase of the first input clock CKIA is later than the phase of the divided clock CKD, the PD 121 may transmit the down detection signal D_DOWN to the CP 122.

According to an embodiment, the CP 122 may supply charge to the LF 123 or discharge the charge of the LF 123 based on the received phase difference signal. In other words, the CP 122 may convert the phase difference signal to a movement of charges. For example, when the CP 122 receives the up detection signal D_UP, the CP 122 may perform a positive charge pumping operation and supply charge to the LF 123. As another example, when the CP 122 receives the down detection signal D_DOWN, the CP 122 may perform a negative charge pumping operation and discharge the charge of the LF 123.

Referring to FIG. 6, the CP 122 may include a switch 122c turned on by logic high of the up detection signal D_UP and a switch 122d turned on by logic high of the down detection signal D_DOWN. When a first charge pump current source 122a receives the up detection signal D_UP, the first charge pump current source 122a may supply current to the LF 123. When the second charge pump current source 122b receives the down detection signal D_DOWN, the second charge pump current source 122b may drain the current of the LF 123.

According to an embodiment, the LF 123 may provide the voltage controlled oscillating unit 124 with an oscillation control voltage VCTR corresponding to the charge charged or discharged by the CP 122. The LF 123 may be implemented by various filters, e.g., a low-pass filter, a band-pass filter, and a high-pass filter. The LF 123 is illustrated as a passive element, but the LF 123 may also be implemented using an active element.

Referring to FIG. 6, the LF 123 may include a first capacitor C1, a second capacitor C2, and a resistor R1. The first capacitor C1 may generate the oscillation control voltage VCTR by charging or discharging the charge output from the CP 122. The resistor RI may be designed to have a certain time constant to prevent a sudden change in the current or voltage of the LF 123. The second capacitor C2 may absorb an impulse current that flows when the PLL is locked.

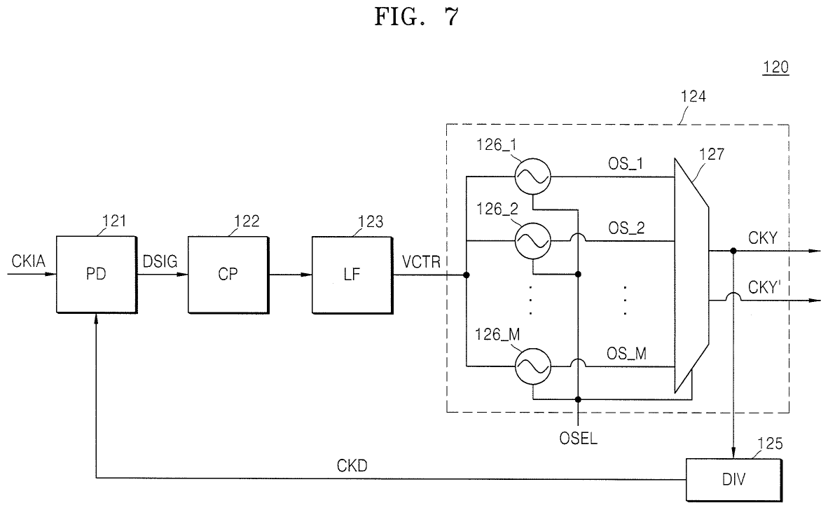

FIG. 7 is a diagram for explaining in detail the second frequency conversion circuit 120 according to an embodiment. Referring to FIG. 7, the VCO 124 may include first through M^{th} voltage controlled oscillators 126_1 through 126_M and an oscillation voltage selection circuit 127. The VCO 124 may provide the oscillation signal output from one of the first through M^{th} voltage controlled oscillators 126_1 through 126_M based on the received oscillator selection signal OSEL as the second conversion clock CKY and/or inverted second conversion clock CKY′.

As an example, the oscillator selection signal OSEL may be provided to the first through M^{th} voltage controlled oscillators 126_1 through 126_M. In this case, at least one of the first through M^{th} voltage controlled oscillators 126_1 through 126_M may be activated based on the oscillator selection signal OSEL, and others of the first through M^{th} voltage controlled oscillators 126_1 through 126_M may be deactivated. An oscillation signal (e.g., a first oscillation signal OS_1) output from an activated one among the first through M^{th} voltage controlled oscillators 126_1 through 126_M may be output as the second conversion clock CKY via the oscillation voltage selection circuit 127. In addition, the oscillation voltage selection circuit 127 may output the inverted second conversion clock CKY′ by inverting the oscillation signal (e.g., the first oscillation signal OS_1) output from the activated one among the first through Mtn, voltage controlled oscillators 126_1 through 126_M.

As another example, the oscillator selection signal OSEL may be provided to the oscillation voltage selection circuit 127. The oscillation voltage selection circuit 127 may select and output an oscillation signal (e.g., a second oscillation signal OS_2) to be output as the second conversion clock CKY based on the oscillator selection signal OSEL. In addition, the oscillation voltage selection circuit 127 may output the second inverted conversion clock CKY′ by inverting the oscillation signal (e.g., the second oscillation signal OS_2). For example, the oscillation voltage selection circuit 127 may include a multiplexer that receives the oscillator selection signal OSEL as a control input and selects one of the first through M^{th} oscillation signals OS_1 through OS_M, and an inverter that inverts the second conversion clock CKY.

As another example, the oscillator selection signal OSEL may be provided as a combination of the examples described above to the first through M^{th} voltage controlled oscillators 126_1 through 126_M, and the oscillation voltage selection circuit 127. In this case, one of the first through M^{th} voltage controlled oscillators 126_1 through 126_M that have been activated by the oscillator selection signal OSEL may output an oscillation signal (e.g., the first oscillation signal OS_1), and the oscillation voltage selection circuit 127 may not output the other oscillation signals (e.g., the second through M^{th} oscillation signals OS_2 through OS_M) except for the output oscillation signal (e.g., the first oscillation signal OS_1). In other words, the oscillation voltage selection circuit 127 may output only a voltage of the voltage controlled oscillator 126 selected by the oscillator selection signal OSEL as the second conversion clock CKY and the inverted second conversion clock CKY′.

According to an embodiment, each of first through M^{th} voltage controlled oscillators 126_1 through 126_M may output a voltage having a different frequency signal from each other. For example, the first voltage controlled oscillator 126_1 may output the oscillation signal OS_1 of a frequency of about 1 Gbps to about 3 Gbps, the second voltage controlled oscillator 126_2 may output the oscillation signal OS_2 of a frequency of about 3 Gbps to about 5 Gbps, and so forth. In this case, when the output clock CKO is to have a frequency of about 4 Gbps to the DUT 300, the test logic 200 may output the oscillator selection signal OSEL to select the second voltage controlled oscillator 126_2 to the first through M^{th} voltage controlled oscillators 126_1 through 126_M and/or the oscillation voltage selection circuit 127. These frequency values may be varied.

The DIV 125 according to an embodiment may receive the second conversion clock CKY and output the divided clock CKD in which the frequency thereof has been divided. For example, when the second conversion clock CKY is to be the first input clock CKIA multiplied by k (k is an integer of one or more), the DIV 125 may transmit to the PD 121 the divided clock CKD in which the frequency of the second conversion clock CKY has been divided by k. The PD 121 may generate the phase difference signal for correcting the phase difference by comparing the first input clock CKIA with the divided clock CKD in which the frequency of the second conversion clock CKY has been divided by k.

The DIV 125 may be designed in various types of circuitries capable of dividing frequencies and may include parallel or serial counters, and a counter may include at least one flip-flop. For example, the counter may be implemented in various ways such as a Modulo-n counter, a ring counter, a cyclic shift register counter, and a binary coded decimal (BCD) counter.

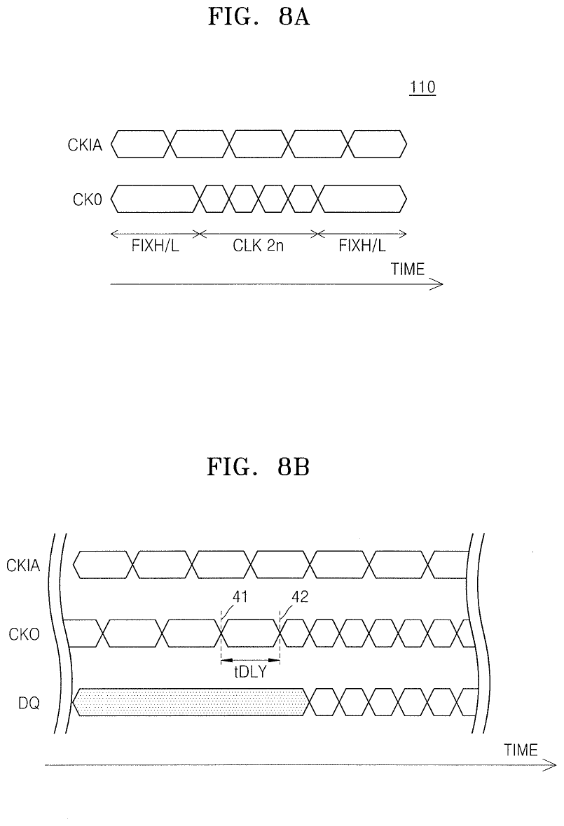

FIGS. 8A and 8B are illustrate the first input clock CKIA, the output clock CKO, and the data DQ in the first frequency conversion circuit 110, according to embodiments.

According to an embodiment, the first frequency conversion circuit 110 may receive the first input clock CKIA and the second input clock CKIB and perform an XOR operation to output the first conversion clock CKX. The selection circuit 130 may receive the first conversion clock CKX and output the received first conversion clock CKX after increasing amplitude thereof as the output clock CKO.

In other words, the output clock CKO illustrated in FIGS. 8A and 8B may be equal or similar to the first conversion clock CXK. The second input clock CKIB may be shifted in phase by about 90 degrees with respect to the first input clock CKIA, as illustrated in FIG. 4.

Referring to FIG. 8A, the first frequency conversion circuit 110 may output the output clock CKO by performing the XOR operation on the first input clock CKIA and the second input clock CKIB. The output clock CKO may include a clock having a first frequency that is twice the input frequency of the first input clock CKIA in a first time period CLK 2n. In this case, the first frequency is a frequency at which the DUT 300 performs a write operation or a read operation.

The first frequency conversion circuit 110 may output the output clock CKO including a clock of a low frequency, e.g., lower than the frequency of the second conversion clock CKY. required by the DUT 300 in a second time period FIXH/L. For example, the first frequency conversion circuit 110 may output a first signal including a signal of a low frequency or a direct current (DC) signal in the second time period FIXH/L and may output a second signal of the first frequency in the first time period CLK 2n.

According to an embodiment, in the second time period FIXH/L, the first frequency conversion circuit 110 may receive from the test logic 200 signals that are fixed at logic high or logic low as the first input clock CKIA and the second input clock CKIB, respectively. In other words, the first frequency conversion circuit 110 may receive a signal that is maintained as a DC signal during the second time period FIXH/L. As another example, the first frequency conversion circuit 110 may receive from the test logic 200 alternating current (AC) signals in which the first input clock CKIA and the second input clock CKIB have the same phase. In this case, the first frequency conversion circuit 110 may output the DC signal in the second time period FIXH/L as the DC signal or two signals having the same phase are received. For example, the second time period FIXH/L may include an initialization operation of the DUT 300 in which the speed or an operation mode of the DUT 300 is determined after power is supplied to the DUT 300. In addition, the output clock CKO in the second time period FIXH/L may include a preparation operation for increasing the frequency of the output clock CKO in the first time period CLK 2n.

Referring to FIG. 8B, the first frequency conversion circuit 110 may generate the output clocks CKO of a relatively low frequency and a relatively high frequency, respectively. The relatively low frequency may be generated before a time point 42 and the relatively high frequency may be generated after the time point 42. The relatively low frequency may be the frequency in the second time period FIXH/L of FIG. 8A and the relatively high frequency may be the frequency in the first time period CLK 2n.

Referring to FIG. 8B, the test logic 200 may provide a command for synchronizing a frequency of the data DQ signal with the frequency of the output clock CKO to the first frequency conversion circuit 110 at a time point 41. When the first frequency conversion circuit 110 receives a command from the test logic 200, after the time point 42 delayed by a delay time tDLY, the first frequency conversion circuit 110 may output the first frequency signal on which the XOR operation has been performed on the first input clock CKIA and the second input clock CKIB.

The test logic 200 may output the data DQ signal that is the same as or similar to the first frequency to the DUT 300. The DUT 300 may receive the output clock CKO as a signal for capturing the data DQ signal. For example, when the DUT 300 is of a graphics double data rate (DDR) (GDDR) type, the output clock CKO may be received as a write clock (or a data clock (WCK) according to the Joint Electron Device Engineering Council (JEDEC) standard). When the DUT 300 is of a low power DDR (LPDDR) type, the output clock CKO may be received as a data strobe (or DQS according to the JEDEC standard). In other words, the first frequency conversion circuit 110 may generate the first conversion clock CKX as a signal with which the DUT 300 captures the data DQ signal, and the first conversion clock CKX may be output as the output clock CKO via the selection circuit 130 to the DUT 300.

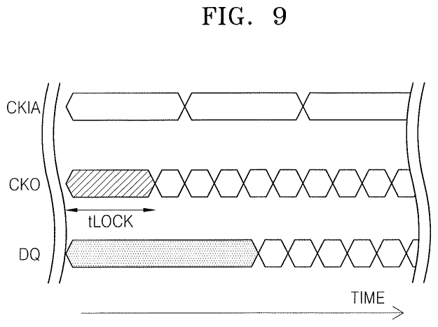

FIG. 9 illustrates the input clock CKIA, the output clock CKO, and the data DQ in the second frequency conversion circuit 120, according to an embodiment. Referring to FIG. 9, the second frequency conversion circuit 120 may receive the first input clock CKIA, perform a phase locking operation on the received first input clock CKIA, and output the second conversion clock CKY obtained by multiplying the frequency of the first input clock CKIA by k. The selection circuit 130 may receive the second conversion clock CKY and output the received second conversion clock CKY after increasing amplitude thereof as the output clock CKO. In other words, the phase of the output clock CKO illustrated in FIG. 9 may be the same as or similar to the phase of the second converted clock CKY.

Referring to FIG. 9, the second frequency conversion circuit 120 may take a certain locking time tLOCK while performing the phase locking operation, and thereafter, the second frequency conversion circuit 120 may generate the output clock CKO based on the second conversion clock CKY in which the frequency of the first input clock CKIA has been multiplied by four. In FIG. 9, the output clock CKO obtained by multiplying the input frequency of the first input clock CKIA by four is shown. The second frequency conversion circuit 120 may output the output clock CKO obtained by multiplying the frequency of the first input clock CKIA by various numbers.

The DUT 300 may receive the output clock CKO as a signal for capturing the data DQ signal. For example, when the DUT 300 is of the GDDR type, the output clock CKO may be received as a write clock (or a data clock (WCK) according to the JEDEC standard). When the DUT 300 is of an LPDDR type, the output clock CKO may be received as a data strobe signal (or DQS according to the JEDEC standard). In other words, the second frequency conversion circuit 120 may generate the second conversion clock CKY as a signal with which the DUT 300 captures the data DQ signal, and the second conversion clock CKY may be output as the output clock CKO via the selection circuit 130 to the DUT 300.

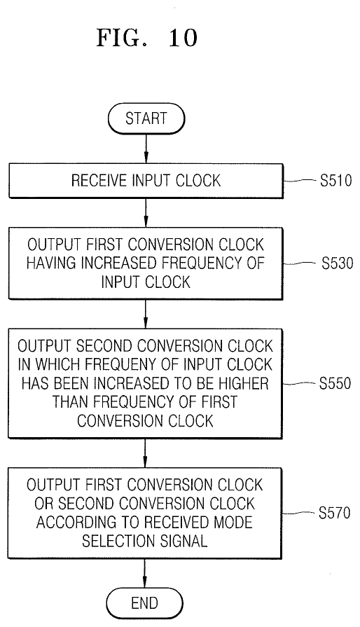

FIG. 10 is a flowchart of a method of generating the output clock CKO for testing a semiconductor device, according to an embodiment.

The socket board 100 may receive the first and second input clocks CKIA and CKIB have phases shifted by about 90 degrees from each other from the test logic 200 (S510).

The socket board 100 may output the first conversion clock CKX in which the frequencies of the first and second input clocks CKIA and CKIB has been increased (S530). The first frequency conversion circuit 110 may output the first conversion clock CKX by performing the XOR operation on the first input clock CKIA and the second input clock CKIB, and may output the inverted first conversion clock CKX′ in which the first conversion clock CKX has been inverted. In other words, the first frequency conversion circuit 110 may output the first conversion clock CKX having a first frequency by multiplying the input frequency of the first and second input clocks CKIA and CKIB by a fixed multiplier, e.g., two.

The socket board 100 may output the second conversion clock CKY in which the input frequency of the first input clocks CKIA has been increased to a second frequency higher than the first frequency of the first conversion clock CKX (S550). For example, since the first frequency conversion circuit 110 including the XOR multiplies a frequency of an input signal by two, the second frequency conversion circuit 120 may be provided to multiply the input frequency of the input signal by a multiplier greater than two. The second frequency conversion circuit 120 may receive the first input clock CKIA and multiply the frequency of the first input clock CKIA through a phase clocking operation. In addition, the second frequency conversion circuit 120 may multiply the input frequency of the first input clock CKIA by the greater multiplier or more based on an oscillation signal generated by one of the plurality of voltage controlled oscillators that generate oscillation frequencies of different bands from each other.

The socket board 100 may amplify the first conversion clock CKX or the second conversion clock CKY according to the mode selection signal MSEL received from the test logic 200 and may output the amplified clock as the output clock CKO (S570).

Since operations S530 and S550 are performed in the first frequency conversion circuit 110 and the second frequency conversion circuit 120, respectively, operations S530 and S550 may be performed independently. For example, operation S530 may be performed after operation S550, may be performed in a reverse order, or operations S530 and S550 may be performed simultaneously.

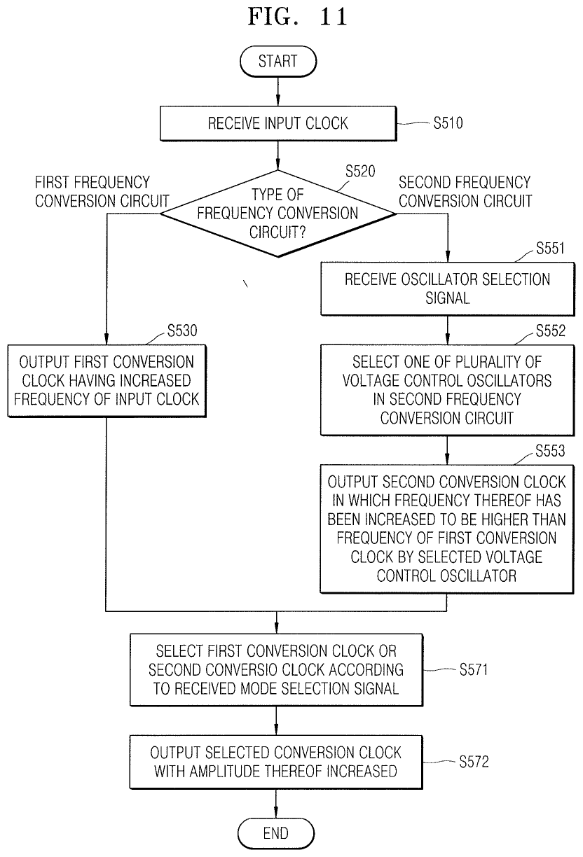

FIG. 11 is a detailed flowchart of a method of generating the output clock CKO for testing a semiconductor device, according to an embodiment. For convenience of explanation, descriptions already given with reference to FIG. 10 are omitted.

A frequency conversion circuit may be divided into the case of the first frequency conversion circuit 110 and the case of the second frequency conversion circuit 120 (S520).

The first frequency conversion circuit 110 may output the first conversion clock CKX in which frequencies of the first and second clocks CKIA and CKIB have been increased by receiving the first and second clocks CKIA and CKIB and performing the XOR operation on the frequencies of the first and second clocks CKIA and CKIB, respectively (S530).

The second frequency conversion circuit 120 may receive the oscillator selection signal OSEL (S551) and select one of the first through M^{th} voltage controlled oscillators 126_1 through 126_M according to the received oscillator selection signal OSEL (S552). Each of the first through M^{th} voltage controlled oscillators 126_1 through 126_M may output different bandwidth from each other. The second conversion clock CKY has a second frequency higher than the first frequency of the first conversion clock CKX based on a frequency band of the selected voltage controlled oscillator 126 (S553).

The socket board 100 may select the first conversion clock CKX or the second conversion clock CKY according to the received mode selection signal MSEL (S571), and amplifies and outputs the selected conversion clock as the output clock CKO (S572). For example, when the mode selection signal MSEL has the first value, the first conversion clock CKX output from the first frequency conversion circuit 110 may be output as the output clock CKO. As another example, when the mode selection signal MSEL has the second value, the second conversion clock CKY output from the second frequency conversion circuit 120 may be output as the output clock CKO.

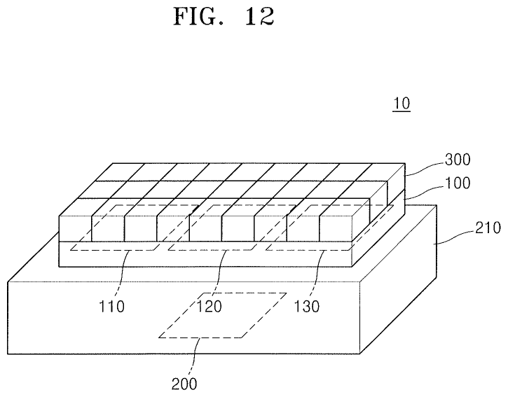

FIG. 12 is a diagram for explaining the test system 10 according to an embodiment. According to an embodiment, the socket board 100 may include the first frequency conversion circuit 110, the second frequency conversion circuit 120, and the selection circuit 130. In other words, the socket board 100 may include the clock converter 107. The clock converter 107 may be included in each of the first through M^{th} socket chips 105_1 through 105_M. The test logic 200 may be in an automatic test equipment (ATE) 210.

The socket board 100 may be electrically connected to the test logic 200. The socket board 100 may output the output clock CKO to the DUT 300 based on various signals received from the test logic 200. As discussed with reference to FIG. 2, the socket board 100 may include pins for receiving various signals and voltages from the test logic 200 or for transmitting various signals and voltages to the test logic 200, and the test logic 200 may also include pins for receiving various signals and voltages from the socket board 100 or for transmitting various signals and voltages to the socket board 100. Similarly, each of the socket boards 100 and the DUTs 300 may include pins for transmitting and receiving various signals and voltages.

At least one of the plurality of the DUTs 300 may be electrically connected to the socket board 100 to receive the output clock CKO and the data DQ, and may transmit the data DQ to the test logic 200 via the socket board 100.

According to embodiments, when the test logic 200 tests the DUT 300, the socket board 100 may transmit the output clock CKO having various frequency bands to the DUT 300 based on the first and second input clocks CKIA and CKIB. The socket board 100 may select one of the first and second conversion clocks CKX and CKY that have been output from the first frequency conversion circuit 110 and the second frequency conversion circuit 120 based on the mode selection signal MSEL, respectively, and may transmit the selected conversion clock to the DUT 300. When testing whether the data DQ is normally received/transmitted in a high frequency band, the second frequency conversion circuit 120 may output the output clock CKO. When testing whether the data DQ is normally received/transmitted in a low frequency band, the first frequency conversion circuit 110 may output the output clock CKO.

According to an example embodiment, a mode in a socket board may be changed such that a clock having a bandwidth required by a DUT is output, and thus, clocks of various bandwidths may be generated without having separate devices. Accordingly, the cost of replacing a test system may be reduced, and various types of DUTs may be tested with a single test system.

One or more embodiments provides a method of converting a clock for testing a device under test (DUT) that has various bandwidths by using mode changes, without replacing a test device, and a clock converter and a test system performing the method.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A clock converter to output a clock signal for testing a semiconductor device, the clock converter comprising:
a clock input terminal to receive an input clock having an input frequency;
a first frequency conversion circuit to receive the input clock and output a first conversion clock having a first frequency by increasing the input frequency using a fixed multiplier;
a second frequency conversion circuit to receive the input clock and output a second conversion clock having a second frequency, greater than the first frequency, by increasing the input frequency using a variable multiplier; and
a selection circuit to output the first conversion clock or the second conversion clock according to a mode selection signal.

2. The clock converter as claimed in claim 1, wherein the input clock includes a first input clock and a second input clock, the first frequency conversion circuit is to receive the first input clock and the second input clock, and the second frequency conversion circuit is to receive the first input clock.

3. The clock converter as claimed in claim 2, further comprising a transmission line branched from the clock input terminal to the first frequency conversion circuit and the second frequency conversion circuit,
wherein each of the first frequency conversion circuit and the second frequency conversion circuit is to receive the first input clock.

4. The clock converter as claimed in claim 2, wherein:
the first frequency conversion circuit is to output the first conversion clock by performing an exclusive OR (XOR) operation on the first input clock and the second input clock, and
the second frequency conversion circuit is to output the second conversion clock based on detection of a phase difference between a divided clock, which is the second conversion clock fed back and divided, and the first input clock.

5. The clock converter as claimed in claim 4, wherein:
the second frequency conversion circuit includes a plurality of voltage controlled oscillators, and
the second frequency conversion circuit is to output an oscillating signal from one of the plurality of voltage controlled oscillators based on an oscillator selection signal.

6. The clock converter as claimed in claim 5, wherein the oscillator selection signal is to activate at least one of the plurality of voltage controlled oscillators and deactivate others.

7. The clock converter as claimed in claim 5, wherein the second frequency conversion circuit further includes an oscillation voltage selection circuit, and
the oscillation voltage selection circuit is to select one of oscillation signals received from the plurality of voltage controlled oscillators, based on the oscillator selection signal, and output the selected oscillation signal and an inverted signal of the selected oscillation signal.

8. The clock converter as claimed in claim 2, wherein:
the first frequency conversion circuit is to output an inverted first conversion clock,
the first conversion clock is obtained by performing an XOR operation on the first input clock and the second input clock, and
the inverted first conversion clock has phase inverted from the first conversion clock.

9. The clock converter as claimed in claim 1, wherein the first conversion clock includes a first time period and a second time period, wherein:
in the first time period, the first conversion clock is a clock on which an XOR operation has been performed on a first input clock and a second input clock having a phase different by about 90 degrees from the first input clock, and
in the second time period, the first conversion clock includes a direct current signal.

10. (canceled)

11. The clock converter as claimed in claim 1, further comprising an input termination, wherein the input termination is connected in parallel to the clock input terminal and the first frequency conversion circuit, and an impedance of the input termination matches an input impedance of the clock converter.

12. The clock converter as claimed in claim 1, wherein the selection circuit includes a multiplexer and an amplifier, wherein:
the multiplexer is to receive the first conversion clock and the second conversion clock via an input terminal of the multiplexer, receive the mode selection signal via a control terminal of the multiplexer, and output the first conversion clock or the second conversion clock to the amplifier, and
the amplifier is to amplify and output the first conversion clock or the second conversion clock based on a driving voltage of the amplifier.

13. A semiconductor test system configured to test a semiconductor device, the semiconductor test system comprising:
automatic test equipment (ATE) including a test logic, the test logic to transmit and receive data for testing the semiconductor device, output an input clock having an input frequency, and output a mode selection signal having different values according to a frequency band of an output clock for testing the semiconductor device; and
a socket board electrically connected to the ATE, the socket board including a clock converter,
wherein the clock converter includes:
a clock input terminal to receive the input clock;
a first frequency conversion circuit to receive the input clock and output a first conversion clock having a first frequency greater than the input frequency;
a second frequency conversion circuit to receive the input clock and output a second conversion clock having a second frequency greater than the first frequency and
a selection circuit to output the output clock based on the first conversion clock or the second conversion clock according to the mode selection signal to the semiconductor device.

14. The semiconductor test system as claimed in claim 13, wherein:
the socket board includes a plurality of socket chips, and
at least one of the plurality of socket chips is in the clock converter.

15. The semiconductor test system as claimed in claim 14, wherein the socket board further includes a plurality of clock input terminals, wherein:
a first clock input terminal is electrically connected to a clock input terminal of the clock converter in a first socket chip, and
a second clock input terminal is electrically connected to a clock input terminal of the clock converter in a second socket chip.

16. (canceled)

17. The semiconductor test system as claimed in claim 14, wherein signals input to the socket board are branched and input to the plurality of socket chips, and the signals control the clock converter in at least one of the plurality of socket chips.

18. The semiconductor test system as claimed in claim 13, wherein:
the input clock includes a first input clock and a second input clock,
the first frequency conversion circuit is to receive the first input clock and the second input clock, and
the second frequency conversion circuit is to receive the first input clock.

19. (canceled)

20. (canceled)

21. A method of converting a clock signal for testing a semiconductor device, the method comprising:
receiving an input clock having an input frequency;
generating a first conversion clock having a first frequency greater than the input frequency by multiplying the input frequency by a fixed multiplier;
generating a second conversion clock having a second frequency greater than the first frequency by multiplying the input frequency by a variable multiplier; and
outputting the first conversion clock or the second conversion clock according a mode selection signal.

22. The method as claimed in claim 21, further comprising:
when the mode selection signal is a first value, amplifying and outputting the first conversion clock, and
when the mode selection signal is a second value, amplifying and outputting the selected second conversion clock.

23. (canceled)

24. The method as claimed in claim 22, wherein generating the second conversion clock further includes:
receiving an oscillator selection signal; and
selecting one of a plurality of voltage controlled oscillators having different frequency bands based on the oscillator selection signal.

25. The method as claimed in claim 24, wherein selecting one of the plurality of voltage controlled oscillators includes:
activating a voltage controlled oscillator of the plurality of voltage controlled oscillators based on the oscillator selection signal; and
outputting an oscillation signal output from the activated voltage controlled oscillator and an inverted signal of the oscillation signal.
